(19) United States
(12) Patent Application Publication
(10) Pub. No.: US 2011/0089932 A1
(43) Pub. Date: Apr. 21, 2011

(54) Systems and Methods for Monitoring Voltage

(75) Inventors: James A. Stegen, Chicago, IL (US); Mark D. Gunderson, Salem, WI (US); Jeffrey D. Merwin, Buffalo Grove, IL (US)

(73) Assignee: CONTINENTAL AUTOMOTIVE SYSTEMS, INC., Deer Park, IL (US)

(21) Appl. No.: 12/975,815

(22) Filed: Dec. 22, 2010

Related U.S. Application Data
(62) Division of application No. 11/862,184, filed on Sep. 26, 2007.

(51) Int. Cl. G01R 1/20

(52) U.S. Cl. 324/126

(57) ABSTRACT

Methods and systems for monitoring voltage are disclosed, including: a plurality of circuit points, a first bus configured to electrically couple to a voltage measurement device, a first set of switches configured to selectively electrically couple a first subset of the circuit points to the first bus, at least one other bus configured to electrically couple to at least one of: the voltage measurement device and another voltage measurement device, and at least one other set of switches configured to selectively electrically couple at least one other subset of the circuit points to the other bus.

### I. BACKGROUND

The invention relates generally to the field of monitoring voltage levels at circuit locations.

In certain systems (such as hybrid electric vehicle systems, off-road vehicles, industrial applications, power generation applications), large numbers of batteries may be connected in series in order to achieve the high levels of voltage (and thus power) that may be required in those systems.

Individual battery voltage levels typically need to be monitored for performing algorithms such as state-of-health, state-of-charge, etc. Typically, the monitoring system cannot be permanently connected to the battery stack due to leakage current concerns over the life of the system, so a switched monitoring system needs to be utilized. When using a single monitoring system (a single voltage measurement device with a common measurement reference point, for example), each switch can “see” up to the full battery potential. Thus, costly, high-voltage switches are required that can withstand the high voltages in such systems.

### II. SUMMARY

In one respect, disclosed is a voltage monitoring system comprising: a plurality of circuit points; a first bus configured to electrically couple to a voltage measurement device; a first set of switches configured to selectively electrically couple a first subset of the circuit points to the first bus; at least one other bus configured to electrically couple to at least one of: the voltage measurement device and another voltage measurement device; and at least one other set of switches configured to selectively electrically couple at least one other subset of the circuit points to the other bus.

In another respect, disclosed is a method for monitoring a plurality of voltage differences, the method comprising: providing a plurality of circuit points; switchably coupling a first subset of the circuit points to a first bus using a first set of switches; selectively closing one or more of the first set of switches to electrically couple one or more of the circuit points of the first subset to the first bus to enable monitoring of a voltage difference across the one or more of the circuit points of the first subset; switchably coupling at least one other subset of the circuit points to at least one other bus using at least one other set of switches; and selectively closing one or more of the other set of switches to electrically couple one or more of the circuit points of the other subset to the other bus to enable monitoring of a voltage difference across the one or more of the circuit points of the other subset.

In yet another respect, disclosed is a battery pack multistage voltage measurement device comprising: a first measurement stage; and a second measurement stage, wherein one of the first and the second measurement stages is of a lower voltage than the vehicular battery pack.

Numerous additional embodiments are also possible.

### III. BRIEF DESCRIPTION OF THE DRAWINGS

Other objects and advantages of the invention may become apparent upon reading the detailed description and upon reference to the accompanying drawings.

FIG. 1 is a block diagram illustrating a system for monitoring the voltage difference across one or more pairs of circuit points, in accordance with one embodiment.

FIG. 2 is a block diagram illustrating a system for monitoring the voltage difference across one or more pairs of circuit points using a single voltage measurement device, in accordance with one embodiment.

FIG. 3 is a block diagram illustrating a system for monitoring the voltage difference across one or more pairs of circuit points using multiple voltage measurement devices, in accordance with one embodiment.

FIG. 4 is a flow diagram illustrating a method for monitoring the voltage difference across one or more pairs of circuit points, in accordance with one embodiment.

FIG. 5 is a flow diagram illustrating an alternative method for monitoring the voltage difference across one or more batteries in a stack of batteries connected in series, in accordance with one embodiment.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### IV. DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

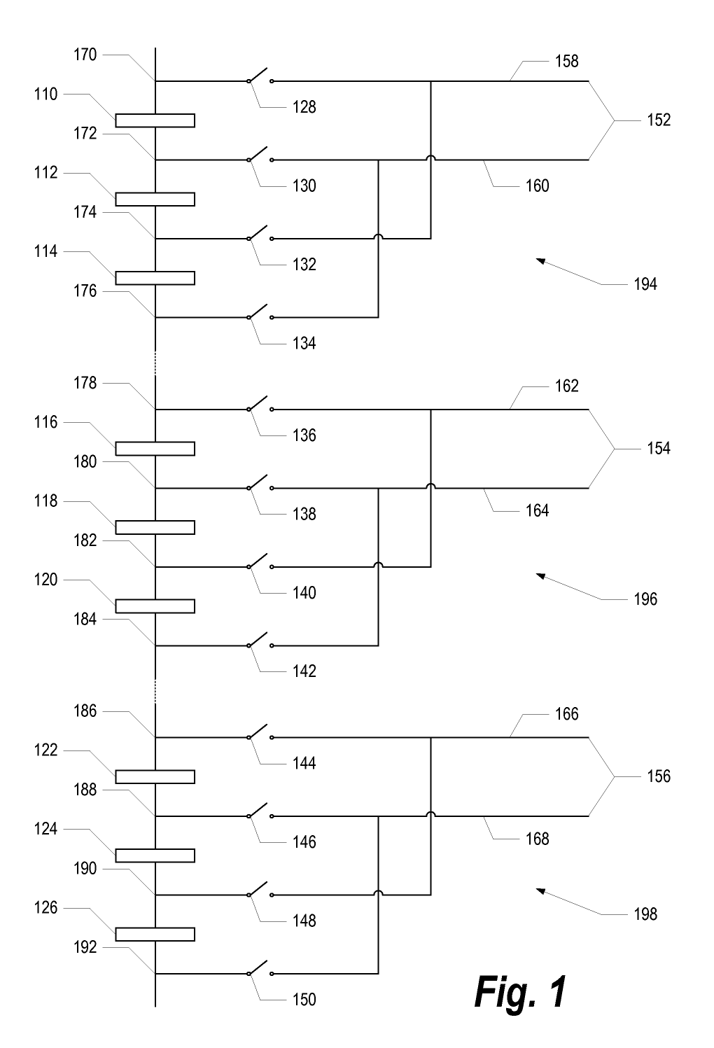

FIG. 1 is a block diagram illustrating a system for monitoring the voltage difference across one or more pairs of circuit points, in accordance with one embodiment.

The voltage monitoring system is configured to measure the voltage across pairs of a plurality of circuit points. In one embodiment, the circuit points may be separating devices connected to each other in series, as is shown, for example, in the FIG. 1. The circuit points/devices may be divided into two or more banks (or stages) (for example, three banks as is shown in FIG. 1) such that: in bank 194 circuit points 170, 172, 174, 176, etc. separate devices 110, 112, 114, etc.; in bank 196 circuit points 178, 180, 182, 184, etc. separate devices 116, 118, 120, etc.; and in bank 198 circuit points 186, 188, 190, 192, etc. separate devices 122, 124, 126, etc. Other configurations of circuit points and devices are possible.

The devices may be resistors, motors, light bulbs, etc. or the devices may be batteries supplying power to other parts of the circuit. In one embodiment, the batteries may be used, for example, to power hybrid, electric, hydrogen cell fuel, etc. type of vehicles. The batteries may also be used in other applications for power generation. In hybrid vehicles, for example, a series of 28 batteries, each being 12 V, may be used to provide a total of about 28*12=336 V (or approximately 500 V of working voltage) to power the vehicle. The batteries may be of any kind such as lead acid, Ni Cd, Li Ion, Ni Metal Hydride, etc.

In order to monitor the voltage across each of these devices, in one embodiment, the circuit points may be electrically coupled to one or more busses, which may then be coupled to one or more voltage measurement devices. In one embodiment, the circuit points may be switchably coupled to busses comprising an odd line and an even line. The circuit points may be coupled to the busses, for example, by alternatingly coupling each of the circuit points to the odd and even lines. In the example shown in the figure, three busses are used: the first bus comprising odd line 158 & even line 160; the second bus comprising odd line 162 and even line 164; and the third bus comprising odd line 166 and even line 168. A larger or a smaller number of busses may be used, thereby creating a larger or a smaller number of groups of circuit points/devices to be monitored.

In one embodiment, the one or more voltage measurement devices may be analog-to-digital converters (ADCs). The voltage measurement devices may also be Sample & Hold, Comparators, Integrators, MUX's, etc.

Switches (such as switches 128, 130, 132, 134, etc.; switches 136, 138, 140, 142, etc.; and switches 144, 146, 148, 150, etc.) may be used to selectively couple the circuit points to the odd lines (such as lines 158, 162, 166, etc.) and even lines (such as lines 160, 164, 168, etc.) of busses 152, 154, 156, etc., thereby enabling selective monitoring of voltage across pairs of circuit points. For example, in order to monitor only the voltage across device 110, switch 128 and switch 130 are closed (while all other switches are open) thereby setting the voltage across bus 152 to the same value as the voltage across device 110. In order to monitor the voltage across device 112, for example, only switch 130 and switch 132 are closed thereby setting the voltage across bus 152 to the same value as the voltage across device 112. Various types of switches may be used such as PhotoMOS/Optocouplers, Relays, MOSFETS, Magnetic Couplers, multimeters, switched capacitor transfer switches, etc.

It should be noted that (assuming the devices are of the same type and current is flowing through them in the same direction), the voltage across consecutive devices will alternate sign when connected to the bus due to the alternating manner that the devices are coupled to the odd and even lines of the bus. The voltage difference across the other devices in bank 194 as well as the devices in bank 196 and bank 198 may be monitored similarly.

In one embodiment, additional switches may be used in order to reverse the polarity on the busses depending on which one of the pairs of circuit points is connected to the bus. In this embodiment, four additional switches may be used to reverse the polarity. In another embodiment, the polarity may instead be reversed using hardware/software logic that may be part of the voltage measurement devices.

In an embodiment where the devices are multiple batteries connected in series, the total voltage across the batteries can be very large. That is, if only one bank and one bus were to be used to monitor the voltage across each of the batteries, each switch would be required to have a fairly large working voltage or voltage rating (in order to avoid unwanted leakage current, for example). If, instead, two or more banks (stages) are used, the switches would only be required to have a fraction of the voltage rating. Thus switches or lower voltage ratings may be used.

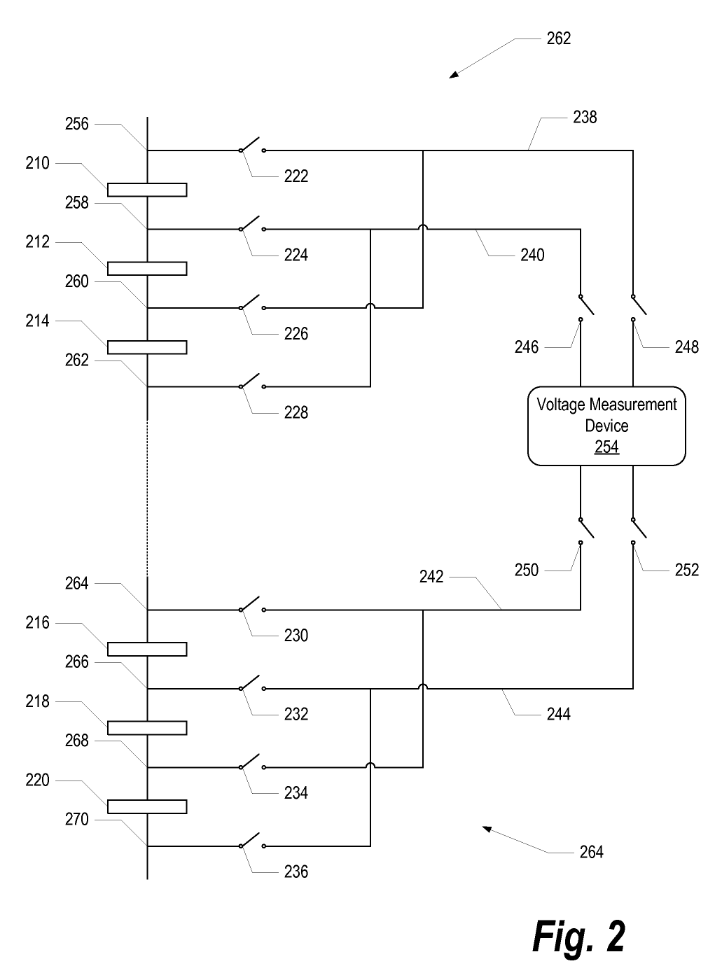

FIG. 2 is a block diagram illustrating a system for monitoring the voltage difference across one or more pairs of circuit points using a single voltage measurement device, in accordance with one embodiment.

Similar to the example system shown in FIG. 1, the voltage monitoring system in this figure is configured to also measure the voltage across pairs of a plurality of circuit points/devices. In this example, the circuit points/devices are divided into two banks (stages) such that: in bank 262 circuit points 256, 258, 260, 262, etc. separate devices 210, 212, 214, etc.; in bank 264 circuit points 264, 266, 268, 270, etc. separate devices 216, 218, 220, etc. In alternative embodiments, additional banks or stages may be used in order to monitor the voltage.

In one embodiment, circuit points that are part of bank 262 are electrically coupled to lines 238 & 240 of the first bus and circuit points that are part of bank 264 are electrically coupled to lines 242 & 244 of the second bus.

Switches 222, 224, 226, 228, etc. and switches 230, 232, 234, 236, etc. are used to selectively couple the circuit points to the odd lines and even lines of the busses, thereby enabling selective monitoring of voltage across pairs of circuit points. For example, in order to monitor only the voltage across device 210, switch 222 and switch 224 are closed (while all other switches are open) thereby setting the voltage across the first bus to the same value as the voltage across device 110, and so on.

In one embodiment, a single voltage measurement device may be used such as voltage measurement device 254. Switches 246 & 248 are used to selectively couple the first bus to voltage measurement device 254 and switches 242 & 244 are used to selectively couple the second bus to voltage measurement device 254. In one embodiment, when a device from bank 262 is being monitored, switches 246 and 248 are closed, and when a device from bank 264 is being monitored, switches 250 and 252 are closed. In alternative embodiments, additional switches may be used in order to reverse the polarity of the voltage on each of the busses depending on which one the devices is being monitored.

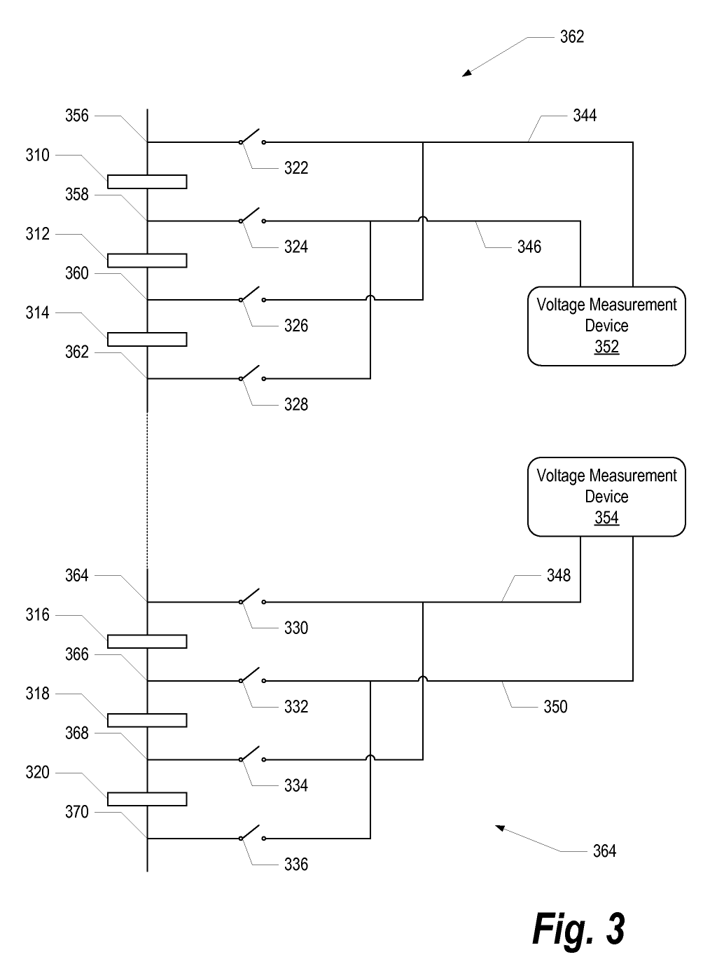

FIG. 3 is a block diagram illustrating a system for monitoring the voltage difference across one or more pairs of circuit points using multiple voltage measurement devices, in accordance with one embodiment.

Similar to the example system shown in FIG. 1, the voltage monitoring system in this figure is configured to also measure the voltage across pairs of a plurality of circuit points/devices. In this example, the circuit points/devices are divided into two banks (stages) such that: in bank 362 circuit points 356, 358, 360, 362, etc. separate devices 310, 312, 314, etc.; and in bank 364 circuit points 364, 366, 368, 370, etc. separate devices 316, 318, 320, etc. In alternative embodiments, additional banks or stages may be used in order to monitor the voltage.

In one embodiment, circuit points that are part of bank 362 are electrically coupled to lines 338 & 340 of the first bus and circuit points that are part of bank 364 are electrically coupled to lines 342 & 344 of the second bus.

Switches 322, 324, 326, 328, etc. and switches 330, 332, 334, 336, etc. are used to selectively couple the circuit points to the odd lines and even lines of the busses, thereby enabling selective monitoring of voltage across pairs of circuit points. For example, in order to monitor only the voltage across device 310, switch 322 and switch 324 are closed (while all other switches are open) thereby setting the voltage across the first bus to the same value as the voltage across device 110, and so on.

In one embodiment, a separate voltage measurement device may be coupled to each one of the busses of each one of the banks. For example, voltage measurement device 352 may be coupled to lines 344 and 346 of bank 362 in order to monitor voltages across devices in bank 364. And voltage measurement device 354 may be coupled to lines 348 and 350 of bank 364 in order to monitor voltages across devices in bank 362. In alternative embodiments, additional switches may be used in order to reverse the polarity of the voltage on each of the busses depending on which one the devices is being monitored.

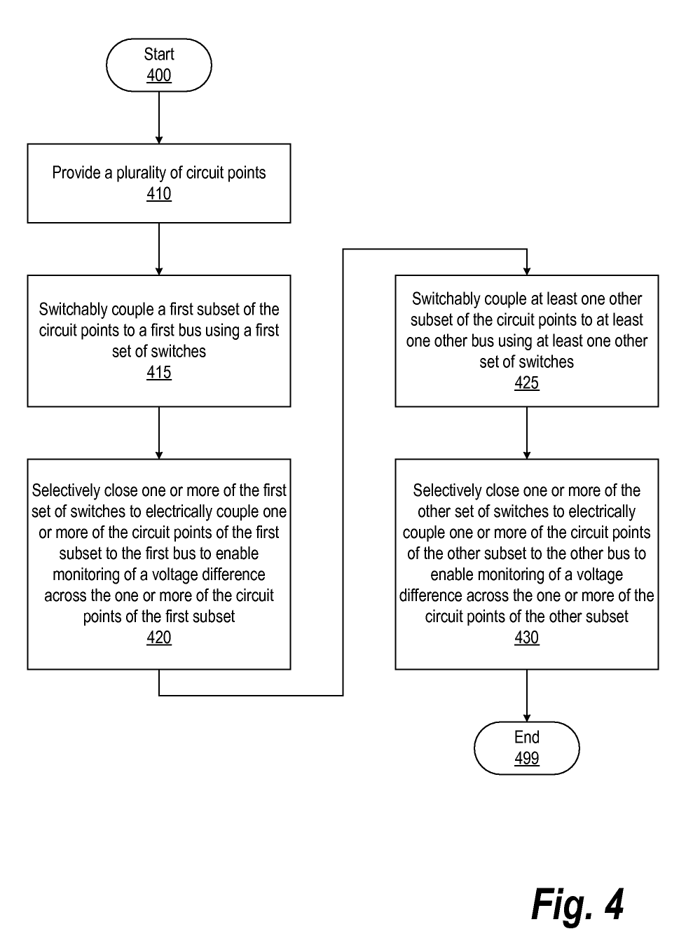

FIG. 4 is a flow diagram illustrating a method for monitoring the voltage difference across one or more pairs of circuit points, in accordance with one embodiment.

Processing begins at 400 whereupon, at block 415, a plurality of circuit points is provided. In one embodiment, the circuit points may connect a plurality of devices, which may be connected to each other in series. The devices may be, for example, batteries, such as the batteries that may be used to power a hybrid, electric, or hydrogen fuel vehicle or battery stacks that may be used in other applications for the power generation.

At block 420, a first subset of the circuit points is switchably coupled to a first bus using a first set of switches, and at block 420, one or more of the first set of switches are selectively closed to electrically couple one or more of the circuit points of the first subset to the first bus to enable monitoring of a voltage difference across the one or more of the circuit points of the first subset. In one embodiment, the first bus comprises an odd line and an even line, with the circuit points alternatingly coupled to the odd line to the even line. A voltage measurement device, such as an analog to digital converter, may be coupled to first bus in order to monitor the voltage difference across the circuit points.

At block 425, at least one other subset of the circuit points is switchably coupled to at least one other bus using at least one other set of switches, and at block 430, one or more of the other set of switches are selectively closed to electrically couple one or more of the circuit points of the other subset to the other bus to enable monitoring of a voltage difference across the one or more of the circuit points of the other subset.

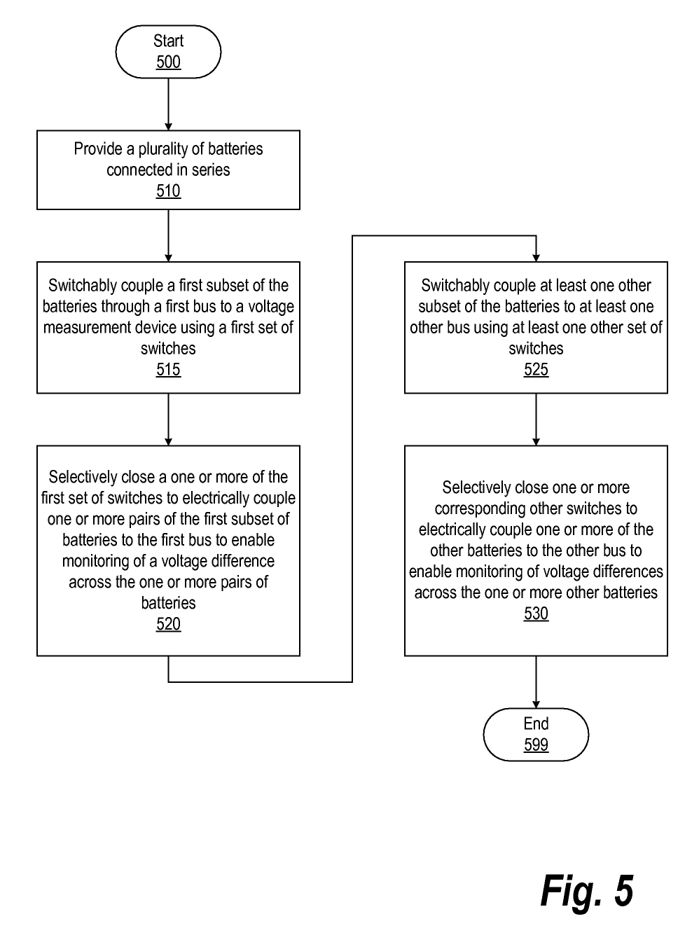

FIG. 5 is a flow diagram illustrating an alternative method for monitoring the voltage difference across one or more batteries in a stack of batteries connected in series, in accordance with one embodiment.

At block 510, a plurality of batteries connected in series is provided. In one embodiment, the batteries may be the type used in vehicles such as hybrid, electric, hydrogen fuel, etc or battery stacks that may be used in other applications for the power generation.

At block 515, a first subset of the batteries is switchably coupled through a first bus to a voltage measurement device using a first set of switches, and at block 520, one or more of the first set of switches are selectively closed to electrically couple one or more pairs of the first subset of batteries to the first bus to enable monitoring of a voltage difference across the one or more pairs of batteries. In one embodiment, the first bus comprises an odd line and an even line, with the battery terminals alternatingly coupled to the odd line to the even line. A voltage measurement device, such as an analog to digital converter, may be coupled to first bus in order to monitor the voltage difference across the batteries.

At block 525, at least one other subset of the batteries is switchably coupled to at least one other bus using at least one other set of switches, and at block 530, one or more corresponding other switches are selectively closed to electrically couple one or more of the other batteries to the other bus to enable monitoring of voltage differences across the one or more other batteries.

Those of skill will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Those of skill in the art may implement the described functionality in varying ways for each particular application, but such implementation decisions should not be interpreted as causing a departure from the scope of the present invention.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed within the following claims.

1. A voltage monitoring system comprising:
a plurality of circuit points;
a first bus configures to electrically couple to a voltage measurement device;
a first set of switches configured to selectively electrically couple a first subset of the circuit points to the first bus;
at least one other bus configured to electrically couple to at least one of: the voltage measurement device and another voltage measurement device; and
at least one other set of switches configured to selectively electrically couple at least one other subset of the circuit points to the other bus.

2. The system of claim 1, wherein a maximum voltage difference across the plurality of circuit points is greater than a maximum voltage difference across the first subset of circuit points and greater than a maximum voltage difference across the other subset of circuit points.

3. The system of claim 1, wherein the first bus and the other bus comprise an odd bus and an even bus and wherein the circuit points are alternatingly coupled to the odd bus and to the even bus.

4. The system of claim 1, wherein the plurality of circuit points connect a plurality of devices in series to each other, and wherein the plurality of circuit points correspond sequentially to an increase in voltage level.

5. The system of claim 4, wherein the plurality of circuit devices are vehicular batteries for powering at least one of a hybrid, an electric, and a hydrogen type of vehicle.

6. The system of claim 1, wherein the voltage measurement device is at least one of: an ADC, a Sample & Hold, a Comparator, an Integrator, and a MUX.

7. The system of claim 1, further comprising:
at least one additional bus configured to electrically couple to at least one of: the voltage measurement device, and another voltage measurement device; and
at least one additional set of switches configured to selectively electrically couple
at least one additional subset of the circuit points to the additional bus

8. A method for monitoring a plurality of voltage difference, the method comprising:
providing a plurality of circuit points;
switchably coupling a first subset of the circuit points to a first bus using a first set of switches;
selectively closing one or more of the first set of switches to electrically couple one or more of the circuit points of the first subset to the first bus to enable monitoring of a voltage difference across the one or more of the circuit points of the first subset;
switchably coupling at least one other subset of the circuit points to at least one other set of switches; and
selectively closing one or more of the other set of switches to electrically couple one or more of the circuit points of the other subset to the other bus to enable monitoring of a voltage difference across the one or more of the circuit points of the other subset.

9. The method of claim 8, further comprising coupling the first bus and the other bus to one or more voltage measurement devices.

10. The method of claim 9, wherein the voltage measurement device is at least one of; an ADC, a Sample & Hold, a Comparator, an Integrator, and a MUX.

11. The method of claim 8, wherein a maximum voltage difference across the plurality of circuit points is greater than a maximum voltage difference across the first subset of circuit points and greater than a maximum voltage difference across the other subset of circuit points.

12. The method of claim 8, further comprising alternatingly coupling the circuit points to an odd bus and to an even bus, wherein the odd bus and the even bus are comprised in the first bus or the other bus.

13. The method of claim 8, wherein the plurality of circuit points connects a corresponding plurality of circuit devices in series and wherein the plurality of circuit points correspond sequentially to an increase in voltage level.

14. The method of claim 13, wherein the plurality of circuit devices are vehicular batteries for powering at least one of a hybrid, an electric, and a hydrogen type of vehicle.

15. The method of claim 8, further comprising:
switchably coupling at least one additional subset of the circuit points to at least one additional bus using at least one additional set of switches; and
selectively closing one or more of the additional set of switches to electrically couple one or more of the circuit points of the additional subset to the additional bus to enable monitoring of a voltage difference across the one or more of the circuit points of the additional subset.

16-21. (canceled)
